(19) United States
(12) Patent Application Publication
(10) Pub. No.: US 2026/0156958 A1
(43) Pub. Date: Jun. 4, 2026

(54) HYBRID BONDED SUBSTRATES AND RELATED METHODS

(71) Applicant: SEMICONDUCTOR COMPONENTS INDUSTRIES, LLC, Scottsdale, AZ (US)

(72) Inventors: Chun Hao CHANG, Zhubei City (TW); Huixian WU, San Jose, CA (US); Weng-Jin WU, Hsinchu City (TW); Hao-Yu CHIEN, Zhubei City (TW); Shih-Chang TAI, Zhubei City (TW)

(73) Assignee: SEMICONDUCTOR COMPONENTS INDUSTRIES, LLC, Scottsdale, AZ (US)

(21) Appl. No.: 18/966,469

(22) Filed: Dec. 3, 2024

(51) Int. Cl. H10F 39/00

(52) U.S. Cl. CPC H10F 39/809; H10F 39/011; H10F 39/8053; H10F 39/8063; H10F 39/811

(57) ABSTRACT

Implementations of an image sensor package may include an image sensor die including a via and a trench both adjacent to a seal ring and a second die bonded to the image sensor die at a hybrid bond. The via may extend into a thickness of the second die to a bond pad included in the second die and the trench may extend into the thickness of the second die.

### BACKGROUND

### 1. Technical Field

Aspects of this document relate generally to semiconductor devices, such as image sensor devices.

### 2. Background

Image sensor devices operate by converting electromagnetic radiation received as photons into electron holes in a semiconductor substrate that are subsequently collected and processed. The quantity of electron holes in each pixel of a pixel array creates an image of the electromagnetic radiation received by the image sensor device.

### SUMMARY

Implementations of an image sensor package may include an image sensor die including a via and a trench both adjacent to a seal ring; and a second die bonded to the image sensor die at a hybrid bond, the second die comprising a bond pad. The via may extend into a thickness of the second die to the bond pad and the trench may extend into the thickness of the second die.

Implementations of an image sensor package may include one, all, or any of the following:

The trench may be located between a scribe line region of the image sensor die and the seal ring.

The via may extend further into the thickness of the second die than the via.

The trench may be unfilled.

A microlens material or a planarization material may fill the trench.

The image sensor die further may include a microlens array coupled to a color filter array coupled to a pixel array.

The trench may extend across corners of the image sensor die.

Implementations of a method of forming an image sensor package may include providing an image sensor die and a second die; hybrid bonding the image sensor die and the second die; forming a patterned layer over a pixel array included in a largest planar surface of the image sensor die; and, using the patterned layer, simultaneously etching a via and a trench both adjacent to a seal ring that extends through a thickness of the image sensor die and into a thickness of the second die.

Implementations of a method of forming an image sensor package may include one, all, or any of the following:

The method may include removing the patterned layer and singulating the image sensor die and the second die adjacent to the trench.

The method may further include singulating using sawing.

The method may include stopping etching of the via at a bond pad included in the second die.

The method may include applying an overetch time during the etching to extend the trench further through the thickness of the second die than the via.

The method may include forming a color filter array on the pixel array; and forming microlenses onto the color filter array.

The method may include forming a color filter array on the pixel array; forming microlenses onto the color filter array using a microlens material; and, while forming the microlenses, filling the trench with the microlens material.

The method may include removing the microlens material from the trench.

The method may include forming a color filter array on the pixel array; forming microlenses onto the color filter array using a microlens material without filling the trench with the microlens material.

Implementations of an image sensor package may include an image sensor die; and a second die bonded to the image sensor die at a hybrid bond; and a via and a trench that both extend into a thickness of the second die through the hybrid bond. The trench may extend into a thickness of the second die through the hybrid bond and extend completely around a perimeter of the image sensor die.

Implementations of an image sensor package may include one, all, or any of the following:

The trench may be located between a scribe line region of the image sensor die and a seal ring.

The trench may be unfilled.

A microlens material or a planarization material may fill the trench.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross-sectional view of an implementation of an image sensor device that includes an image sensor die hybrid bonded to a second die;

FIG. 2 is a cross-sectional view of another implementation of an image sensor device that includes an image sensor die hybrid bonded to a second die;

FIG. 3 is a cross-sectional view of another implementation of an image sensor device showing a scribe line/die street;

FIG. 4 is a top perspective view of an implementation of an image sensor device showing an implementation of a trench;

FIG. 5 is a top view of the image sensor device implementation of FIG. 4;

FIG. 6 is a cross-sectional view of an implementation of an image sensor device after a bonding operation and a patterning operation;

FIG. 7 is a cross-sectional view of the image sensor device implementation of FIG. 6 following an etching operation;

FIG. 8 is a cross-sectional view of the image sensor device implementation of FIG. 7 following a pattern removal operation;

FIG. 9 is a cross-sectional view of implementations of image sensor devices following formation of a color filter array and microlens array thereon; and

FIG. 10 is a cross-sectional view of implementation of image sensor devices following formation of a color filter array and microlens array thereon with the trenches filled with microlens material.

### DESCRIPTION

This disclosure, its aspects and implementations, are not limited to the specific components, assembly procedures or method elements disclosed herein. Many additional components, assembly procedures and/or method elements known in the art consistent with the intended image sensor packages will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such image sensor packages, and implementing components and methods, consistent with the intended operation and methods.

During manufacture of image sensor devices, a first die, such as an image sensor die may be bonded to a second die (or one or more additional die). The second die may be any of a wide variety of semiconductor die types, including, by non-limiting example, a digital signal processor, a microprocessor, a field programmable gate array (FPGA), a memory, a random access memory, a flash memory, an electrically erasable programmable read-only memory (EEPROM), an interposer die, or any other semiconductor device or die type. Hybrid bonding includes bonding a dielectric surface of the first die to a dielectric surface of the second die, as well as bonding metal embedded in the first die to metal embedded in the second die. The dielectric may be the semiconductor substrate material, such as silicon oxide, and the metal may be copper or other metals suitable for hybrid bonding techniques. The bonding of the embedded metal of the first die and the embedded metal of the second die forms a hybrid bond metal interconnect. The embedded metal placed for hybrid bonding purposes may otherwise be referred herein as “hybrid bonding metal.”

Following bonding and other processing, a single stacked die may include an array of image sensor devices, with image sensors in the image sensor die connected to electrical components on the second die. An image sensor device may then be singulated from the array of image sensor devices. Where the singulation is carried out using a mechanical process, like sawing or jet ablating, cracks can form in the image sensor die, the second die, and/or in the hybrid bond interface adjacent to the blade/jet. The cracks can propagate into either die or begin to break/delaminate the hybrid bond which results in yield loss immediately, or potential reliability failures as the device is being used over time under thermal or mechanical stress.

In this document, the term “through-silicon via” is utilized. However, the semiconductor substrate material used to form the image sensor die and the second die may be many other semiconductor substrate types in various implementation including, by non-limiting example, silicon carbide, silicon on insulator, glass, silicon dioxide, gallium arsenide, ruby, sapphire, or any other semiconductor substrate type. Accordingly, as used herein, for the sake of simpler discussion, the term “through-silicon via” also includes vias that extend through the material of the particular semiconductor substrate type in which they are formed including vias that extend through interlayer dielectric and other insulating materials like through-oxide vias.

While the principles in this document are illustrated in the context of hybrid bonded image sensor devices, the concepts could also be applied to any hybrid bonded semiconductor device. Thus, the principles disclosed herein could be applied to hybrid bonded combinations of, by non-limiting example, microprocessors, microcontrollers, microprocessors and memory, power semiconductor devices, power semiconductor devices and memory, or combinations of any other semiconductor device type. Those of ordinary skill will be able to readily appreciate how the principles disclosed herein can be employed to assist with preventing propagation of cracking in various bonded semiconductor die.

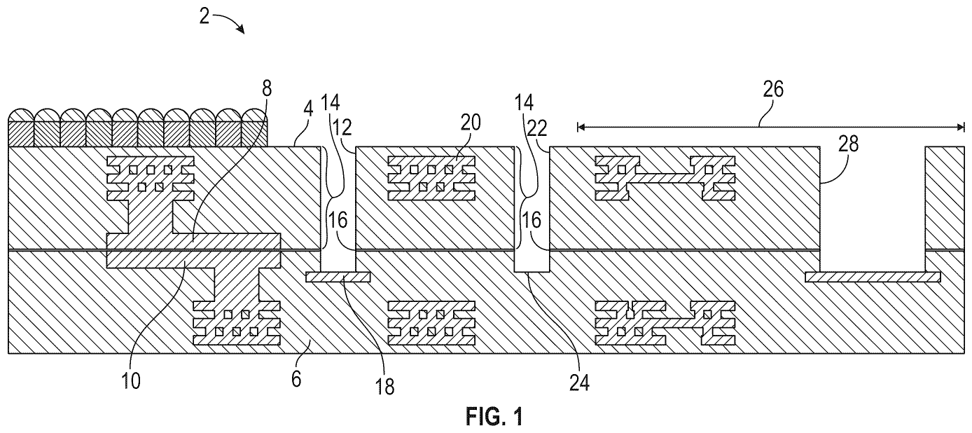

Referring to FIG. 1, an implementation of an image sensor device 2 is illustrated that includes image sensor die 4 hybrid bonded to second die 6 using complimentary metal structures 8, 10 formed in the two die respectively. The second die 6 may be any semiconductor device type disclosed herein. The image sensor device 2 includes a through-silicon via 12 that extends through the thickness 14 of the image sensor die 4 and through the hybrid bond 16 down to pad 18. As illustrated, a seal ring structure 20 is formed from a metallization pattern of traces and vias in the die stack of the image sensor die 4. In this implementation, the seal ring structure does not extend down into the semiconductor substrate material of the image sensor die itself to the hybrid bond 16, which can allow cracks to spread under the seal ring. The through-silicon via 12 is adjacent to the seal ring 20.

Referring to FIG. 1, also adjacent to the seal ring 20 is a trench/via 22. As shown, trench 22 extends through the thickness 14 of the image sensor die, past the hybrid bond 16, and into the material of the second die 6. The end 24 of the trench 22 is in the material of the second die 6 as there is no pad at this location. Because no pad is used here in this implementation, the end 24 of the trench 22 may extend into the thickness of the second die 6 further than the through-silicon via 12, even if the through-silicon via 12 and the trench 22 are etched simultaneously, as there is no etch stop for the trench. In alternative implementations, if an etch stop was desired for the trench 22, a pad could be formed in the semiconductor substrate material of the second die 6 to prevent further etching of the trench 22 past the pad.

To the right of the trench is the scribe line area/die street 26 of the image sensor device in which another via 28 has been formed to allow for access to electronic test structures. The structure in this scribe line area may be substantially or entirely removed during singulation of the image sensor device 2 in various implementations, leaving the trench 22 intact or with one side partially or entirely removed in the as-singulated structure. Because the trench 22 extends through the thickness 14 of the image sensor die past the hybrid bond 16, any cracks that form during singulation in the material of the image sensor die or the second die, or any delamination/separation of the hybrid bond 16 mechanically terminates when reaching the edge of the trench 22. The gap in the material of the image sensor die 4 and second die 6 formed by the trench 22 prevents cracking from the singulation operation from propagating into the image sensor die 4, second die 6, or hybrid bond 16.

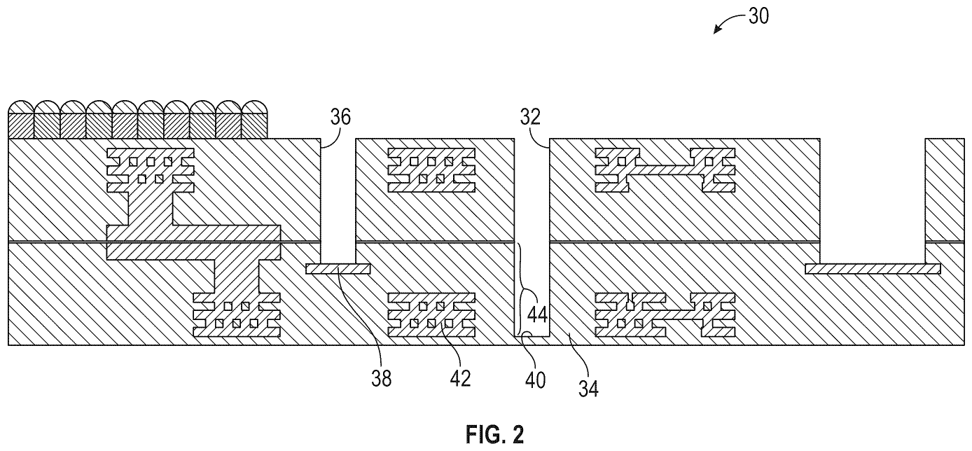

Referring to FIG. 2, another implementation of an image sensor device 30 is illustrated that indicates that the depth of the trench 32 into the thickness 44 of the second die 34 can be deeper than for the through-silicon via 36 as there is no etch stop like the pad 38 for the trench 32 in this implementation during the simultaneous etching process. In this way, the end 40 of the trench 32 can be set to reach down to the seal ring structure 42 in the die stack of the second die 34, which may further prevent any cracks formed in the second die 34 from propagating into the material of the second die 34. An appropriate overetch time can be set to allow the end 40 of the trench 32 to reach the desired location in the thickness 44 of the second die 34.

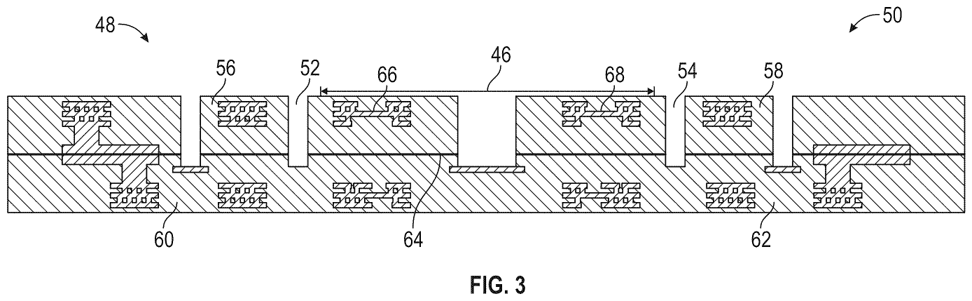

Referring to FIG. 3, two semiconductor device implementations 48, 50 are illustrated joined by scribe line region 46. In this view, the position of the trenches 52, 54 adjacent to the scribe line region 46 enables them to stop the progression of cracking into the material of the two image sensor die 56, 58 or the two second die 60, 62 or delamination along the location of the hybrid bond 64. The trenches 52, 54, as voids, prevent propagation of a crack past the location of the void during singulation in the scribe line region 46. During singulation, as the width of the saw cut may correspond approximately with the indicated width of the scribe line region 46, the edge of the cut may leave the sides of the trenches 52, 54 intact. Alternatively, if the width of the saw cut is wider than the width of the scribe line region 46, the saw cut may remove some or all of the material of the trenches depending on the kerf width of the blade.

FIG. 3 also illustrates how, in some implementations, both the image sensor die 56, 58 and the second die 60, 62 may be thinned prior to hybrid bonding. In other implementations, thinning of the image sensor die 56, 58 and/or the second die 60, 62 may occur after bonding, if at all. In all these structural versions, trenches 52, 54 may be utilized to prevent cracking and delamination.

The trenches 52, 54 may also help limit heat transfer during laser scribing. In some image sensor implementations, laser scribing may be employed through at least some of the die stack of the image sensor to prevent cracking of the interlayer dielectric materials (particularly in low dielectric constant material, i.e., low K material), during subsequent sawing Metal regions 66, 68 like those illustrated in FIG. 3 are used to help absorb laser energy and thus prevent spreading of the cut beyond the scribe line region 46. Because the trenches 52, 54 in FIG. 3 are not filled with any material, heat transfer into the die stack of the image sensor die 56, 58 during the lasering operation may be reduced. Reducing the heat transfer can help prevent damage occurring to active circuitry in the die stack of the image sensor die 56, 58.

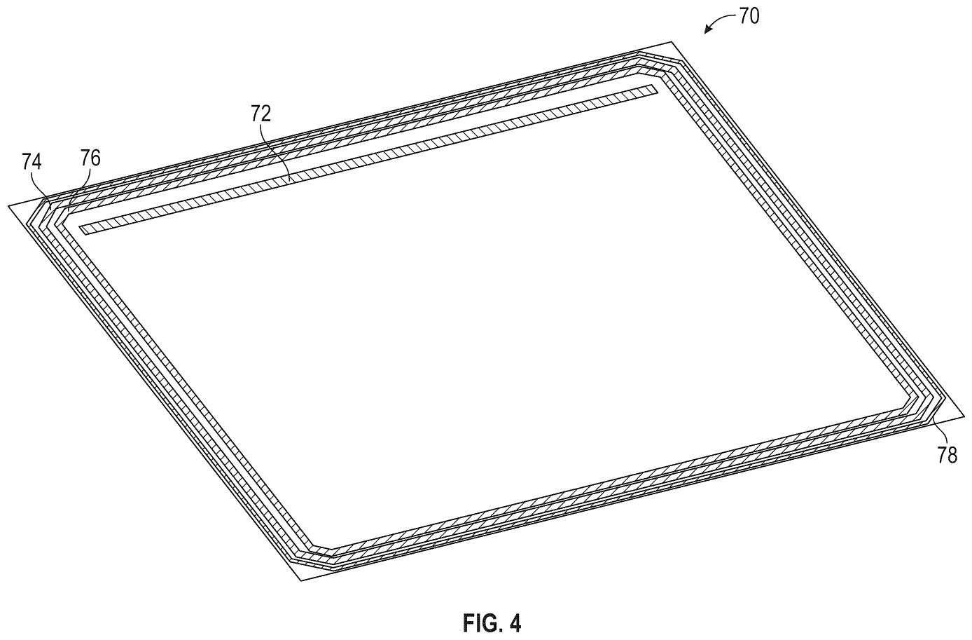

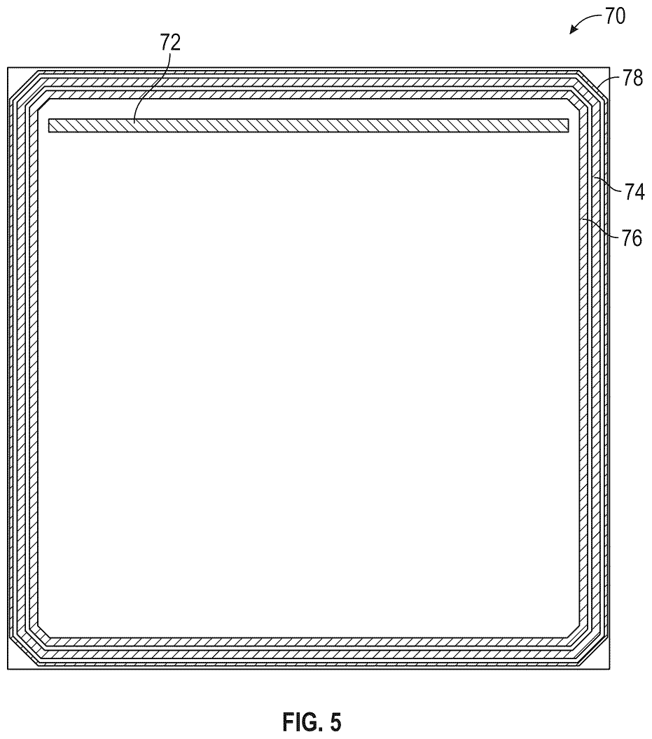

In various structure and method implementations, the location of the trenches may run along one or more sides of the image sensor device. As shown in FIGS. 4-5, the image sensor device may have four sides and be square or rectangular. In some implementations, the trenches may be present on all sides of the image sensor device, positioned adjacent to all of the scribe line regions. In implementations where the trenches are present on two sides, the trenches are may be present adjacent two parallel scribe line regions, such as either the X scribe line regions or adjacent the Y scribe line regions. In some implementations, the trenches may be present adjacent alternating X scribe line regions, alternating Y scribe line regions, or both alternating X scribe line regions and alternating Y scribe line regions.

Referring to FIG. 4, a perspective top view of an image sensor device 70 is illustrated in order to show the structure of the bonding and sealing structures without the detail of the pixel array for clarity purposes. In this implementation, the placement of the hybrid bonding metal 72 within the rectangular image sensor device 70 is illustrated as extending along one side of the image sensor device 70, in the form of complementarily arranged lines of metal in an upper image sensor die and a lower second die. In other implementations, the hybrid bonding metal may be located in many other locations, such as, by non-limiting example, opposing sides, three sides, all four sides, multiple lines, crossing patterns, curved patterns, dotted patterns, or any other desired configuration that achieves the desired amount of hybrid bonding between the image sensor die and the second die. Also illustrated in FIG. 4 are seal rings 74, 76 which are arranged concentrically with seal ring 76 within the perimeter of seal ring 74. While the use of two seal rings is illustrated in the implementation of FIG. 4, a single seal ring, or more than two seal rings could be utilized in other image sensor device implementations. Also, while the seal rings are illustrated as continuous, they could be composed of discontinuous structure or portions/sections in some implementations. Trench 78 is also illustrated and is concentrically arranged around seal ring 74.

Referring to FIG. 5, a top view of the image sensor device 70 is illustrated which further shows the relative positioning of the hybrid bonding metal 72, the seal rings 74, 76, and the trench 78. Here the spacing and the adjacent relationship between the trench 78 and the seal ring 74 can be seen. In the implementations of FIGS. 4-5, the seal rings 74, 76 and the trench 78 all extend across the corners of the image sensor device 70 rather than extending adjacent out to the corners. Because the corner regions of the die may be most vulnerable to forming chipping defects during singulation by sawing, this extension of the trench 78 across the corners helps minimize the odds that a chip would get across the trench for any particular die. In other image sensor device implementations, the seal rings 74, 76, and the trench may extend to the corners maintaining the same spacing along the four sides of the image sensor device 70.

The spacing between the trench 78 and the seal ring 74 can be determined by the width of the trench desired and/or the degree of cracking mitigation desired. The trench 78 forms a first line of defense against cracking and chipping. The width of the trench 78 may vary based on available area, tool etching restrictions, substrate material, etc. A wider spacing between the trench 78 and the seal ring 74 would provide additional margin, therefore more protection, while a narrower spacing may provide less margin, or less protection. While the trench implementation 78 illustrated in FIGS. 4-5 is a continuous trench, in other implementations, the trench may have breaks or spaces or may be formed as a set of spaced apart openings set at a desired distance that is capable of creating the desired crack and delamination mitigation.

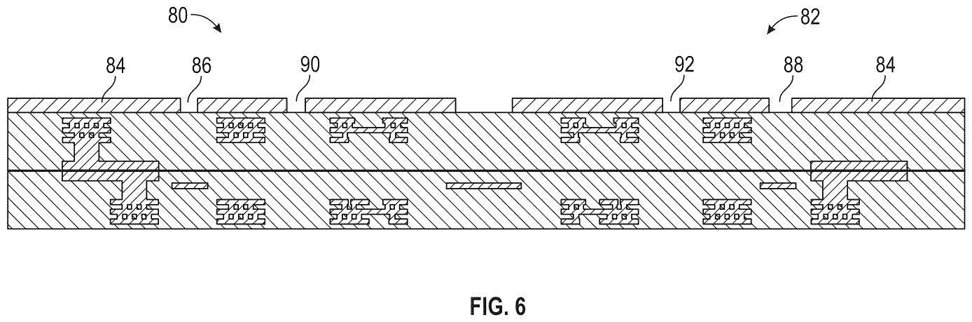

The various image sensor device implementations disclosed herein may be made using various methods of forming an image sensor package. Referring to FIG. 6, a cross-sectional view of an implementation of a first stage in forming two image sensor devices 80, 82 is illustrated. In the first stage, a wafer stack is shown including an image sensor die and a second die that have been hybrid bonded together, each die including dielectric layers. In FIG. 6, the wafer stack is shown after a patterned layer 84 has been formed thereon. The patterning layer may be formed using, by non-limiting example, photolithography, screen printing, stencil printing, transfer printing, or another method capable of placing the locations of the through silicon vias and the trenches in the desired locations. As illustrated, the patterned layer includes openings 86, 88 that correspond with the location of the through-silicon vias. The patterned layer also includes openings 90, 92 that correspond with the location of where the trenches will be formed. The material of the patterning layer may be one that is designed to protect a pixel array during etching and which can be removed from the pixel array after or during etching. In some method implementations, a different removable material may be used to protect the pixel array and any die pads to be used for electrical connections while a different non-removable material (or a permanently attached material) is used to form the openings 86, 88, 90, 92. For example, because the patterned material around the through-silicon vias and the trenches may not need to be removed, the use of a permanently attached (like a polyimide, nitride, or oxide) could be utilized in such implementations. Where the permanently attached material requires etching to form the opening in it, an additional patterning operation may be carried out to form an additional patterned layer on top of the patterned layer 84 prior to etching the desired opening. The additional patterned layer is then removed subsequent to the etching process for the openings 86, 88, 90, 92.

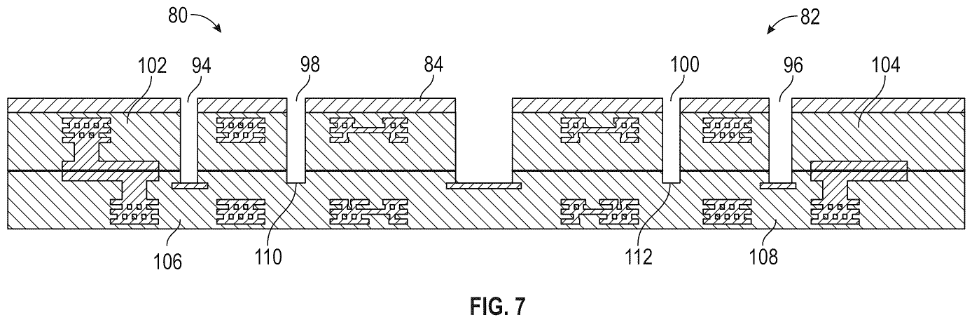

Referring to FIG. 7, the image sensor devices 80, 82 are illustrated at a second stage in the process. The second stage shows the wafer stack following a process that forms the through-silicon vias 94, 96 and the trenches 98, 100 through the openings shown in FIG. 6. Because the patterned layer is designed to form the through-silicon vias 94, 96 and trenches 98, 100, they are formed simultaneously. In various implementations, the forming process may be, by non-limiting example, etching, dry etching, wet etching, or lasering, or any other process capable of forming the through silicon vias and the trenches simultaneously in the material of the semiconductor substrate used in the image sensor die 102, 104 and the second die 106, 108. Where the semiconductor substrate material is silicon, a deep reactive ion etching process may be employed to form the through-silicon vias 94, 96 and the trenches 98, 100. During an etching process, an overetch may be employed which may cause the ends 110, 112 of the trenches 98, 100 to extend further into the thickness of the second die 106, 108 as previously described in this document. In alternative implementations, the through-silicon vias and the trenches may not be formed at the same time, but they are formed in the same process step, using one of the methods mentioned above or another method such as water jet cutting or laser drilling.

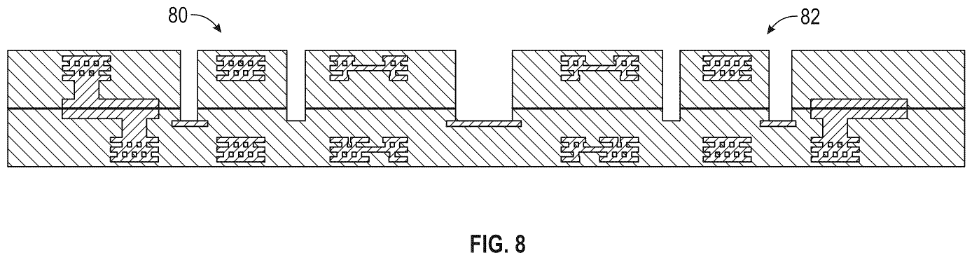

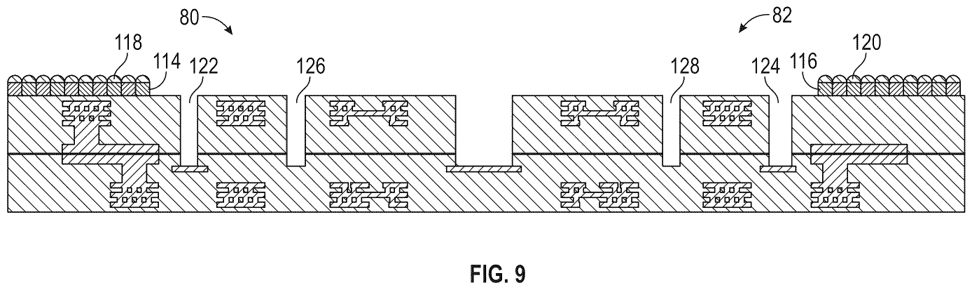

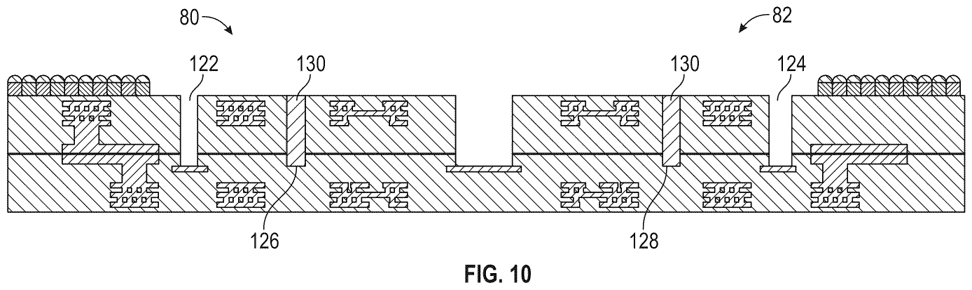

Referring to FIG. 8, the image sensor devices 80, 82 are illustrated at a third stage in the process. The third stage shows the wafer stack following removal of the patterned layer 84 illustrated in FIG. 7. This removal process may include, by non-limiting example, ashing, solvent stripping, washing, abrading, or any other removal process consistent with the material type. At third stage, the image sensor devices 80, 82 could be singulated followed by additional chip-scale packaging processes to complete the process of forming them into image sensor packages. In other method implementations, additional wafer-scale processing may be employed to form additional structures on the image sensor devices at the third stage prior to singulating, such as is shown in FIGS. 9-10 (discussed in further detail below). The additional wafer-scale processing may prepare the image sensor devices 80, 82 for additional chip-scale packaging processes (e.g., glass attach, wire bonding, molding, etc.) or complete or substantially complete the packaging for each image sensor device at the wafer scale followed by singulating. In some implementations, the additional wafer-scale processing may include one or more wafer planarization processes prior to formation of the color filter array and/or the microlenses to help increase die strength.

Referring to FIG. 9, the image sensor devices 80, 82 are illustrated at a fourth stage following the formation of color filter arrays 114, 116 and an array of microlenses 118, 120 over the pixel array region of the image sensor devices 80, 82. In some method implementations, only microlenses may be formed and the color filter arrays may not be included. Note that the image sensor devices 80, 82 in FIG. 9 have through-silicon vias 122, 124 and trenches 126, 128 that do not contain any material following the formation process of the color filter arrays 114, 116 and microlenses 118, 120. In this method implementation, following the formation of the microlenses, the material of the microlenses does not remain in the through-silicon vias 122, 124 and trenches 126, 128. One way to achieve this result is by filling the through-silicon vias 122, 124 and trenches 126, 128 with a temporary material like a planarization material during the microlens formation process and then removing that planarization material after the microlens processing is completed. In such a method implementation, the material of the microlenses never fills the trenches 126, 128, leaving the trenches unfilled. In other method implementations, no planarizing material may be employed and the material of the microlenses may fill or partially fill the trenches 126, 128 but may be fully removed in the final processing step of the microlens process leaving the trenches 126, 128 open.

In other method implementations, as illustrated in FIG. 10, at the fourth stage the images sensor devices 80, 82 include filled trenches 126, 128. For this method implementation, the process may include filling the trenches 126, 128 with the material of the microlenses 130 during the microlens fabrication process or with a planarization material different from the material of the microlenses 130. The microlens material or planarization material in the trenches 126, 128 may act as a stress guard and/or may prevent particles from accumulating in the trenches, which may degrade their effectiveness. To achieve the open through-silicon vias 122, 124, a removable material may fill the through-silicon vias 122, 124 while leaving the trenches 126, 128 exposed before the microlens forming process. In alternative method implementations, the filling of the trenches 126, 128 with the microlens material or planarization material could take place after the formation of the microlenses in a separate process. A wide variety of method implementations may be constructed by those of ordinary skill using the principles disclosed in this document.

In places where the description above refers to particular implementations of image sensor packages and implementing components, sub-components, methods and sub-methods, it should be readily apparent that a number of modifications may be made without departing from the spirit thereof and that these implementations, implementing components, sub-components, methods and sub-methods may be applied to other image sensor packages.

What is claimed is:

1. An image sensor package comprising:
an image sensor die comprising a via and a trench both adjacent to a seal ring; and
a second die bonded to the image sensor die at a hybrid bond, the second die comprising a bond pad;
wherein the via extends into a thickness of the second die to the bond pad; and
wherein the trench extends into the thickness of the second die.

2. The image sensor package of claim 1, wherein the trench is located between a scribe line region of the image sensor die and the seal ring.

3. The image sensor package of claim 1, wherein the trench extends further into the thickness of the second die than the via.

4. The image sensor package of claim 1, wherein the trench is unfilled.

5. The image sensor package of claim 1, wherein one of a microlens material or a planarization material fills the trench.

6. The image sensor package of claim 1, wherein the image sensor die further comprises a microlens array coupled to a color filter array coupled to a pixel array.

7. The image sensor package of claim 1, wherein the trench extends across corners of the image sensor die.

8. A method of forming an image sensor package comprising:
providing an image sensor die and a second die;
hybrid bonding the image sensor die and the second die;
forming a patterned layer over a pixel array comprised in a largest planar surface of the image sensor die; and
using the patterned layer, simultaneously etching a via and a trench, wherein the trench is adjacent to a seal ring and extends through a thickness of the image sensor die and into a thickness of the second die.

9. The method of claim 8, further comprising removing the patterned layer and singulating the image sensor die and the second die adjacent to the trench.

10. The method of claim 9, further comprising singulating using sawing.

11. The method of claim 8, further comprising stopping etching of the via at a bond pad comprised in the second die.

12. The method of claim 11, further comprising applying an overetch time during the etching to extend the trench further through the thickness of the second die than the via.

13. The method of claim 8, further comprising:
forming a color filter array on the pixel array; and
forming microlenses onto the color filter array.

14. The method of claim 8, further comprising:
forming a color filter array on the pixel array;
forming microlenses onto the color filter array using a microlens material; and
while forming the microlenses, filling the trench with the microlens material.

15. The method of claim 14, further comprising removing the microlens material from the trench.

16. The method of claim 8, further comprising:
forming a color filter array on the pixel array;
forming microlenses onto the color filter array using a microlens material without filling the trench with the microlens material.

17. An image sensor package comprising:
an image sensor die;
a second die bonded to the image sensor die at a hybrid bond;
a via that extends into a thickness of the second die through the hybrid bond; and
a trench that extends into a thickness of the second die through the hybrid bond and extends around a perimeter of the image sensor die.

18. The image sensor package of claim 17, wherein the trench is located between a scribe line region of the image sensor die and a seal ring.

19. The image sensor package of claim 17, wherein the trench is unfilled.

20. The image sensor package of claim 17, wherein one of a microlens material or a planarization material fills the trench.
